(19) United States
(12) Patent Application Publication
(10) Pub. No.: US 2018/0261709 A1
(43) Pub. Date: Sep. 13, 2018

(54) SOLAR BATTERY

(71) Applicant: The University of Tokyo, Tokyo (JP)

(72) Inventors: Yoshitaka OKADA, Tokyo (JP); Tomah SOGABE, Tokyo (JP); Yasushi SHOJI, Tokyo (JP)

(21) Appl. No.: 15/538,912

(22) PCT Filed: Dec. 25, 2015
(86) PCT No.: PCT/JP2015/086247

§ 371 Date: Jun. 22, 2017

(30) Foreign Application Priority Data
Dec. 25, 2014 (JP) 2014-262496

(51) Int. Cl. H01L 31/0693; H01L 31/0352; H01L 31/18; H01L 31/0224; H01L 31/05

(52) U.S. Cl. CPC H01L 31/0693; H01L 31/035218; H01L 31/0504; H01L 31/022425; H01L 31/1844

(57) ABSTRACT

A solar battery (1) according to the present invention is configured such that a photovoltaic conversion stack part (17) of a current adjusting solar battery cell (3) has a band gap (Bg4) larger than a band gap (Bg1) in a buried layer (13) of an intermediate-band solar battery cell (2). The current adjusting solar battery cell (3) absorbs light having a wavelength equal to or shorter than a wavelength corresponding to a band gap (Bg4), and an amount of light to be absorbed by the intermediate-band solar battery cell (2) is accordingly reduced, whereby an amount of current which is generated in the intermediate-band solar battery cell (2) can be suppressed, and thus, an amount of heat which is generated in the intermediate-band solar battery cell (2) can be reduced and thermal damage to the solar battery (1) can be prevented. Further, while the amount of current which is generated in the intermediate-band solar battery cell (2) is suppressed, voltage is generated, by light absorption, also in the current adjusting solar battery cell (3) connected in series to the intermediate-band solar battery cell (2). Accordingly, overall output voltage obtained by the solar battery (1) can be increased, whereby the conversion efficiency can be greatly enhanced compared with conventional solar batteries.

### TECHNICAL FIELD

The present invention relates to a solar battery.

### BACKGROUND ART

As clean energy sources, solar batteries have recently received attention. Since the band gap of silicon is approximately 1.1 eV, light having a wavelength longer than approximately 1100 nm, which corresponds to the band gap of silicon, is transmitted through conventional silicon solar batteries. Thus, light included in sunlight and having a wavelength within a long wavelength range cannot be efficiently used. For this reason, intermediate-band solar batteries capable of using light having a wavelength within a long wavelength range have recently received attention (see Patent Document 1, etc.).

For example, Patent Document 1 discloses an intermediate-band solar battery obtained by sequentially stacking, on an n-type GaAs substrate, an n-layer made from n-type GaAs, an i-layer having a plurality of GaSb quantum dots dispersed in a GaAs barrier layer, and a p-layer made from p-type GaAs. In the intermediate-band solar battery, electrons are excited from a valence band directly to a conduction band of the GaAs forming the i-layer so that voltage and current are generated. In addition, electrons are excited also between the valence band and an intermediate band and between the intermediate band and the conduction band so that voltage and current can be generated.

In this case, the band gap between the valence band and the intermediate band and the band gap between the intermediate band and the conduction band are each smaller than the band gap between the valence band and the conduction band. Accordingly, electrons are excited from the valence band to the intermediate band and are excited from the intermediate band to the conduction band, by light having a longer wavelength compared to the case where electrons are excited from the valence band directly to the conduction band. In such an intermediate-band solar battery, electrons are excited even by light having a wavelength within a long wavelength range so that voltage and current are generated. Thus, in the intermediate-band solar battery, larger current can be obtained and the conversion efficiency can be enhanced, compared with a mere silicon solar battery having no intermediate band formed therein. Note that the conversion efficiency herein refers to the general performance of a solar battery, and is the percentage of a value obtained by dividing, by the energy of light incident on the solar battery, a solar battery output which is a product of an output voltage and an output current from the solar battery.

### CITATION LIST

### Patent Literature

Patent Document 1: Japanese Patent Laid-Open No. 2006-114815

### SUMMARY OF INVENTION

### Technical Problem

Although, in such an intermediate-band solar battery, a larger amount of current can be generated by a plurality of band gaps which are obtained by forming an intermediate band, large heat generation easily occurs due to the obtained current so that energy as the heat is lost. This leads to a problem that a high conversion efficiency is difficult to actually achieve. Further, when sunlight is concentrated by a high light concentration ratio in order to achieve a high conversion efficiency and is applied onto the intermediate-band solar battery, much larger current flows, whereby an amount of generated heat becomes considerably large. This may cause thermal damage.

The present invention has been made in view of the above problems, and an object thereof is to provide a solar battery to which thermal damage can be prevented and of which a conversion efficiency can be greatly enhanced compared with conventional solar batteries.

### Solution to Problem

A solar battery according to the present invention is characterized by including: an intermediate-band solar battery cell that has a quantum dot superlattice layer including a plurality of quantum dot layers stacked on each other, each quantum dot layer including a buried layer having a plurality of quantum dots arranged therein, the quantum dot superlattice layer having therein an intermediate band formed by superposition of wavefunctions among the quantum dots; and a current adjusting solar battery cell that has a photovoltaic conversion stack part including at least a p-type photovoltaic conversion layer and an n-type photovoltaic conversion layer and that is formed on a light incidence side of the intermediate-band solar battery cell, wherein in the current adjusting solar battery cell, the photovoltaic conversion stack part has a band gap larger than a band gap in the buried layer of the intermediate-band solar battery cell.

### Advantageous Effects of Invention

In the solar battery according to the present invention, light having a wavelength corresponding to the band gap in the photovoltaic conversion stack part is absorbed by the current adjusting solar battery cell, and an amount of light to be absorbed by the intermediate-band solar battery cell is accordingly reduced, whereby an amount of current which is generated in the intermediate-band solar battery cell can be reduced. An amount of heat which is generated in the intermediate-band solar battery cell can be accordingly reduced, and thermal damage can be prevented. In addition, in the solar battery according to the present invention, while an amount of current which is generated in the intermediate-band solar battery cell is suppressed by means of the current adjusting solar battery cell, voltage is generated, by absorption of light having a wavelength corresponding to the band gap, also in the current adjusting solar battery cell connected in series to the intermediate-band solar battery cell. Thus, overall output voltage obtained by the solar battery can be increased by means of the intermediate-band solar battery cell and the current adjusting solar battery cell which are connected in series to each other. Consequently, the conversion efficiency of the solar battery can be greatly enhanced compared with conventional solar batteries.

### BRIEF DESCRIPTION OF DRAWINGS

FIG. 1 is a schematic diagram illustrating the entire configuration of a solar battery according to an embodiment of the present invention;

FIG. 2 is a schematic diagram illustrating a band structure in a region where a plurality of quantum dot layers are stacked in an intermediate-band solar battery cell;

FIG. 3 is a diagram showing the relationship among band gaps of the intermediate-band solar battery cell and a band gap of a current adjusting solar battery cell;

FIG. 4A is a schematic diagram showing the relationship among band gaps of an intermediate-band solar battery used as a comparative example in simulation, and FIG. 4B shows a current-voltage curve calculated as a result of the simulation;

FIG. 5A is a schematic diagram illustrating the band gap arrangement of a solar battery used as an experimental example in simulation, and FIG. 5B shows a current-voltage curve of the solar battery calculated as a result of the simulation;

FIG. 6 is a diagram showing the relationship between the band gap energy of the band gap in a photovoltaic conversion stack part and the conversion efficiency of the solar battery;

FIG. 7 is a schematic diagram illustrating the entire configuration of a solar battery as an experimental example;

FIG. 8 is a diagram showing a measurement result of current-voltage characteristics of the solar battery as the experimental example when a light concentration ratio is 72; and

FIG. 9A shows a combination of materials for forming the quantum dots, the buried layer, and the photovoltaic conversion stack part in a case where a substrate is made from GaAs or Ge, and FIG. 9B shows a combination of materials for forming the quantum dots, the buried layer, and the photovoltaic conversion stack part in a case where the substrate is made from InP.

### DESCRIPTION OF EMBODIMENTS

1. Configuration of Solar Battery According to Embodiment of Present Invention

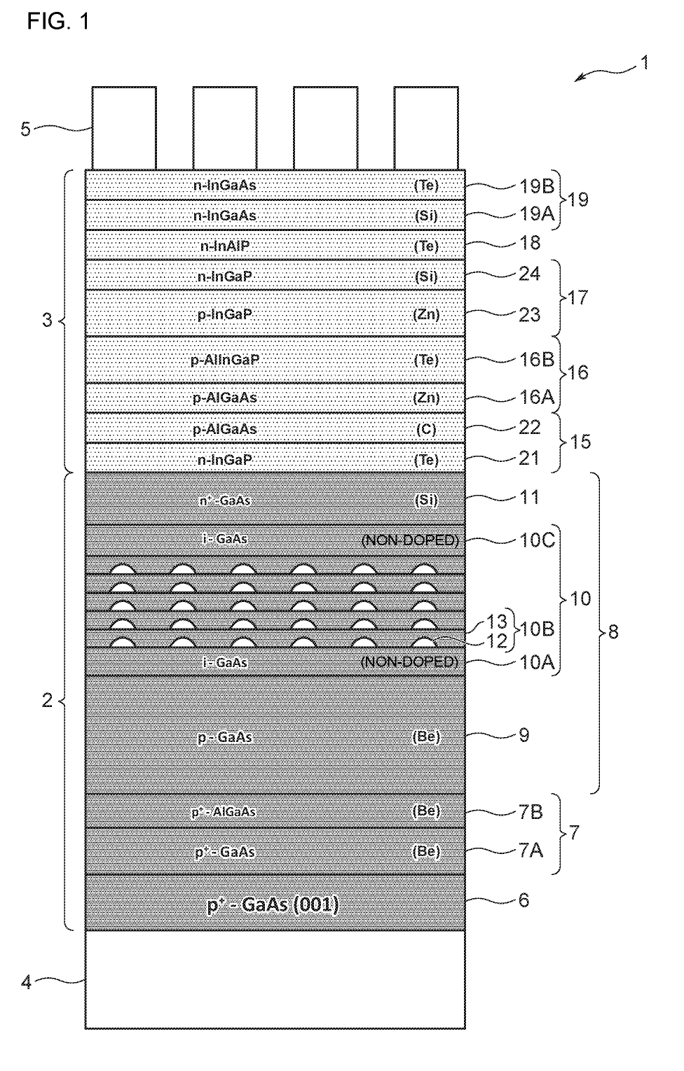

In FIG. 1, reference numeral 1 denotes a solar battery according to the present invention. The solar battery 1 has a configuration in which an intermediate-band solar battery cell 2, a current adjusting solar battery cell 3, and surface electrodes 5 are sequentially formed on a back electrode 4, and the current adjusting solar battery cell 3 and the intermediate-band solar battery cell 2 are connected in series to each other. The solar battery 1 is configured such that, when light is incident through the surface electrodes 5 toward the back electrode 4, the light can reach the intermediate-band solar battery cell 2 via the current adjusting solar battery cell 3.

In this case, in the solar battery 1, light being incident on the surface electrodes 5 side and having a small wavelength is absorbed by the current adjusting solar battery cell 3 so that voltage and current are generated in the current adjusting solar battery cell 3, and light having other wavelengths can pass through the current adjusting solar battery cell 3 and reach the intermediate-band solar battery cell 2. In the solar battery 1 of practical use, light having a longer wavelength than light that is absorbed by the current adjusting solar battery cell 3 might pass through the current adjusting solar battery cell 3 and enter the intermediate-band solar battery cell 2. Accordingly, in the solar battery 1, light having a certain wavelength and having passed through the current adjusting solar battery cell 3 is absorbed by the intermediate-band solar battery cell 2. As a result, voltage and current can be generated also in the intermediate-band solar battery cell 2. The solar battery 1 is configured such that the voltage and current generated in the current adjusting solar battery cell 3 and the intermediate-band solar battery cell 2 can be outputted, as output voltage and output current from the solar battery 1, for example, to an external circuit (not illustrated) which is connected to the surface electrodes 5 and the back electrode 4.

As described above, in the solar battery 1 according to the present invention, incident light having a wavelength not larger than a prescribed wavelength is absorbed by the current adjusting solar battery cell 3, and thus, while voltage and current are generated in the current adjusting solar battery cell 3, light to enter the intermediate-band solar battery cell 2 can be reduced. As a result, in the solar battery 1, light having a wavelength equal to or shorter than the prescribed wavelength is absorbed by the current adjusting solar battery cell 3, and an amount of light to be absorbed by the intermediate-band solar battery cell 2 is accordingly reduced. Thus, an amount of current which is generated in the intermediate-band solar battery cell 2 can be suppressed, and an amount of heat which is generated in the intermediate-band solar battery cell 2 can be accordingly reduced.

Moreover, in the solar battery 1, while an amount of current which is generated in the intermediate-band solar battery cell 2 is suppressed by means of the current adjusting solar battery cell 3, voltage is generated, by light absorption, also in the current adjusting solar battery cell 3 which is connected in series to the intermediate-band solar battery cell 2. Therefore, overall output voltage obtained by the solar battery 1 can be increased by means of the intermediate-band solar battery cell 2 and the current adjusting solar battery cell 3.

Here, the back electrode 4 is formed of a metallic member such as Au and Ag, and the intermediate-band solar battery cell 2 is formed on a surface of the back electrode 4. In the intermediate-band solar battery cell 2, a buffer layer 7 and an intermediate-band photovoltaic conversion stack part 8 are sequentially formed on a substrate 6 made from a single crystal such as P⁺-GaAs (001). The back electrode 4 is formed on the back surface of the substrate 6. In FIG. 1, the names of materials forming respective layers are shown as an example. Here,“p-”, “i-”, and “n-” preceding the material names in FIG. 1 indicate that the corresponding materials are a p-type semiconductor, an intrinsic semiconductor, and an n-type semiconductor, respectively. The semiconductors with “+” being added to the character indicating the semiconductor conductive type, such as the semiconductors with “p⁺-”, have more carries than those without “+” being added thereto.

In the intermediate-band solar battery cell 2, the buffer layer 7 to which impurities are added and which is formed of a III-V semiconductor is formed. The buffer layer 7 buffers the lattice constant mismatch between the substrate 6 and the intermediate-band photovoltaic conversion stack part 8 so as to enhance the crystallinity of the intermediate-band photovoltaic conversion stack part 8. In the embodiment according to the present invention, the buffer layer 7 has a two-layer structure composed of a first buffer layer 7A which is made from p⁺-GaAs and doped with Be, and a second buffer layer 7B which is formed on the first buffer layer 7A and which is made from p⁺-AlGaAs and doped with Be. The first buffer layer 7A and the second buffer layer 7B are each formed to have much impurities added thereto and have many carriers therein so that current easily flows therethrough. Note that the buffer layer 7 having the two-layer structure composed of the first buffer layer 7A and the second buffer layer 7B is described in this embodiment, but the present invention is not limited to this, and a single buffer layer or a buffer layer composed of three or more layers may be adopted.

The intermediate-band photovoltaic conversion stack part 8 has a configuration in which a p-type semiconductor layer 9, a quantum dot superlattice layer 10, and an n-type semiconductor layer 11 are sequentially stacked. The p-type semiconductor layer 9 is formed on the buffer layer 7. The p-type semiconductor layer 9 is formed of a Ge-doped p-type III-V semiconductor such as p-GaAs. The n-type semiconductor layer 11 is formed of a semiconductor that is of, e.g., a Si-doped n-type such as n⁺-GaAs and that is the same III-V semiconductor as that of the p-type semiconductor layer 9.

In the intermediate-band photovoltaic conversion stack part 8, the quantum dot superlattice layer 10 is formed between the p-type semiconductor layer 9 and the n-type semiconductor layer 11. Holes generated in the quantum dot superlattice layer 10 can be diffused into the p-type semiconductor layer 9 by an inner electric field generated at the boundary between the p-type semiconductor layer 9 and the quantum dot superlattice layer 10. On the other hand, electrons generated in the quantum dot superlattice layer 10 can be diffused into the n-type semiconductor layer 11 by an inner electric field generated at the boundary between the n-type semiconductor layer 11 and the quantum dot superlattice layer 10.

Here, the quantum dot superlattice layer 10 has a configuration in which a plurality of quantum dot layers 10B are stacked between a first quantum dot buffer layer 10A and a second quantum dot buffer layer 10C. In practical use, the quantum dot layers 10B each having a plurality of regularly arranged quantum dots 12 are stacked in the quantum dot superlattice layer 10, and thus, the quantum dots 12 are regularly arranged also in a direction perpendicular to the substrate 6. The quantum dot superlattice layer 10 has a configuration in which the plurality of quantum dots 12 are arranged in a three-dimensionally regular form. The first quantum dot buffer layer 10A and the second quantum dot buffer layer 10C are each formed of a semiconductor that is of a non-doped i-type such as i-GaAs and that is the same III-V semiconductor as those of the p-type semiconductor layer 9 and the n-type semiconductor layer 11.

All the plurality of quantum dot layers 10B formed between the first quantum dot buffer layer 10A and the second quantum dot buffer layer 10C have the identical configurations. For example, each of the quantum dot layers 10B has a configuration in which the plurality of quantum dots 12 arranged at a prescribed interval are embedded in a buried layer 13 formed of a semiconductor that is of a non-doped i-type such as i-GaAs and that is the same III-V semiconductor as those of the p-type semiconductor layer 9 and the n-type semiconductor layer 11.

All the plurality of quantum dots 12 in the buried layers 13 have the identical configurations, and are each formed of a III-V semiconductor, such as InAs, having a band gap smaller than the band gap in the III-V semiconductor forming each of the buried layers 13. As a result of the arrangement of the quantum dots 12 at the prescribed interval, wavefunctions of electrons in the adjacent quantum dots 12 are superposed one another, whereby an intermediate band is formed.

In the quantum dot layers 10B, the quantum dots 12 are desired to be regularly arranged at an interval of 5 to 20 nm, for example. Further, in the present embodiment, each of the quantum dots 12 is formed into a particular shape, and is desired to have a diameter of 10 to 20 nm when being measured on the basis of a picture taken by a microscope such as an atomic force microscope (AFM). Moreover, the buried layers 13 each cover the surrounding areas of the quantum dots 12, and the quantum dots 12 in one of the adjacent quantum dot layers 10B can be arranged in non-contact with the quantum dots 12 in the other of the adjacent quantum dot layers 10B. At the boundary between the first quantum dot buffer layer 10A and the quantum dot layers 10B, the buried layers 13 compensate crystal lattice strain which is caused by the difference in lattice constant between the quantum dots 12 in the quantum dot layers 10B and the first quantum dot buffer layer 10A.

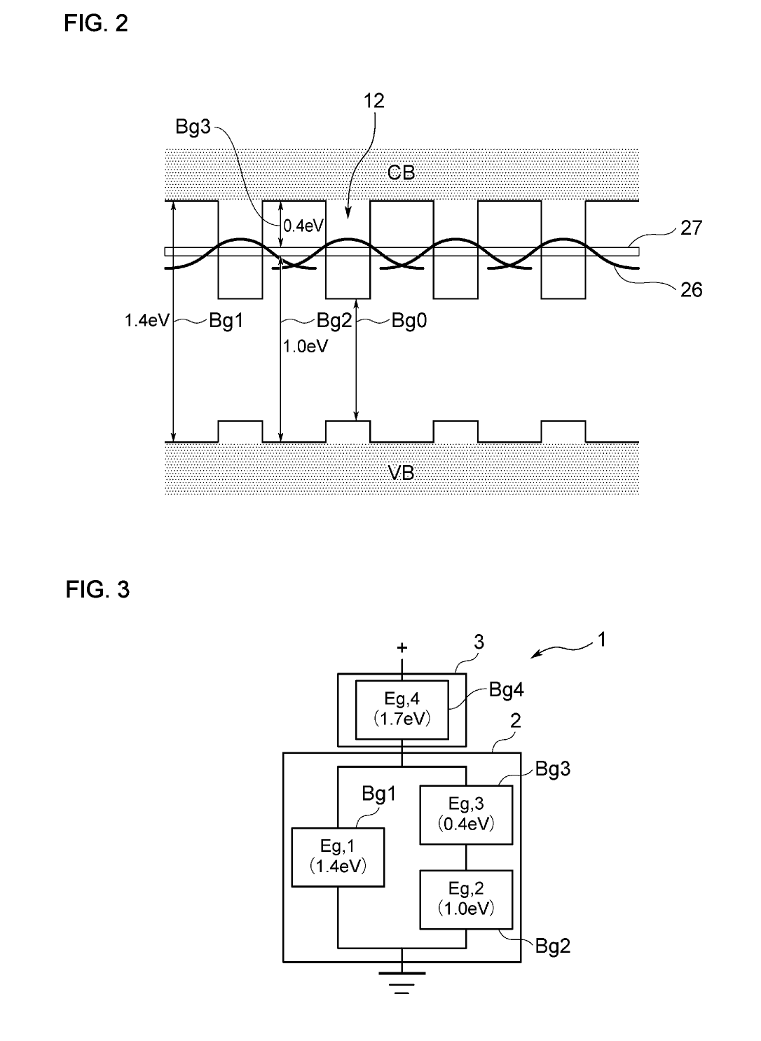

FIG. 2 is a schematic diagram illustrating a band structure in a region where the plurality of quantum dot layers 10B are stacked. In the region where the plurality of quantum dot layers 10B are stacked, the quantum dots 12 each having a band gap Bg0 smaller than a band gap Bg1, which is between the upper end of a valence band VB and the lower end of a conduction band CB of the III-V semiconductor forming the corresponding buried layer 13, are arranged at the prescribed interval. As a result, wavefunctions 26 of electrons in the adjacent quantum dots 12 are superposed one another, and an intermediate band 27 in which electrons in one of the adjacent quantum dots 12 can move into the other adjacent quantum dot 12 can be formed.

Accordingly, in the region where the plurality of quantum dot layers 10B are stacked, one band gap Bg2 can be formed between the upper end of the valence band VB and the intermediate band 27, separately from the band gap Bg1 of the III-V semiconductors forming the buried layers 13, and further, another band gap Bg3 can be formed between the intermediate band 27 and the conduction band CB. In the present embodiment, in the region where the plurality of quantum dot layers 10B are stacked, the band gap Bg2 which is smaller than the band gap Bg1 of the III-V semiconductors forming the buried layers 13 but is larger than the band gap Bg3 formed between the intermediate band 27 and the conduction band CB, can be formed between the upper end of the valence band VB and the intermediate band 27. Moreover, in the region where the plurality of quantum dot layers 10B are stacked, the band gap Bg3 which is smaller than the band gap Bg1 of the III-V semiconductors forming the buried layers 13 and than the band gap Bg2 formed between the upper end of the valence band VB and the intermediate band 27, can be formed between the intermediate band 27 and the conduction band CB.

The quantum dot superlattice layers 10 each absorb a part of incident light having a wavelength corresponding to the band gaps Bg1 of the III-V semiconductors forming the buried layers 13. As a result of absorption of this light, electrons in the valence band VB are excited from the valence band VB directly to the conduction band CB, and thus, holes can be formed in the valence band VB and electrons can be generated in the conduction band CB. In addition, the quantum dot superlattice layers 10 each absorb light having a wavelength corresponding to the band gap Bg2 between the upper end of the valence band VB and the intermediate band 27. As a result of absorption of this light, electrons in the valence band VB are excited to the intermediate band 27, and thus, holes can be generated in the valence band VB. Moreover, the quantum dot superlattice layers 10 each absorb light having a wavelength corresponding to the band gap Bg3 between the intermediate band 27 and the conduction band CB. As a result of absorption of this light, the electrons excited to the intermediate band 27 are excited from the intermediate band 27 to the conduction band CB, and thus, electrons can be generated in the conduction band CB.

In the present embodiment, the case has been described where the band gap Bg3 formed between the intermediate band 27 and the conduction band CB is formed to be smaller than the band gap Bg2 formed between the upper end of the valence band VB and the intermediate band 27. However, the present invention is not limited to this case, and the kind of the III-V semiconductors forming the quantum dots 12 or the kind of the III-V semiconductors forming the buried layers 13 may be selected, as appropriate, so as to, for example, form the band gap Bg3 formed between the intermediate band 27 and the conduction band CB, to be larger than the band gap Bg2 formed between the upper end of the valence band VB and the intermediate band 27.

Here, a configuration of other portions of the solar battery 1 is described with reference to FIG. 1 again. As illustrated in FIG. 1, the current adjusting solar battery cell 3 has a configuration in which a tunnel layer 15, a BSF (back surface field) layer 16, a photovoltaic conversion stack part 17, a window layer 18, and a contact layer 19 are sequentially formed on the n-type semiconductor layer 11 of the intermediate-band solar battery cell 2.

The tunnel layer 15 has a configuration in which a p-type tunnel layer 22 formed of, e.g., a C-doped p-type III-V semiconductor such as p-AlGaAs is stacked on an n-type tunnel layer 21 formed of, e.g., a Te-doped n-type III-V semiconductor such as n-InGaP. In the tunnel layer 15, a pn junction is formed by the n-type tunnel layer 21 and the p-type tunnel layer 22. When voltage and current are outputted from the intermediate-band solar battery cell 2 and the current adjusting solar battery cell 3, the intermediate-band solar battery cell 2 applies negative voltage to the n-type tunnel layer 21 and the current adjusting solar battery cell 3 applies positive voltage to the p-type tunnel layer 22. Therefore, forward bias voltage is applied to the pn junction formed by the n-type tunnel layer 21 and the p-type tunnel layer 22 so that tunnel current can flow therethrough.

The tunnel layer 15 is doped with more carrier impurities and the resistance of the tunnel layer 15 is set to be low. Here, the n-type tunnel layer 21 and the p-type tunnel layer 22 are each formed of a III-V semiconductor having a band gap that is larger than the band gap Bg1 of the III-V semiconductors forming the buried layers 13 of the quantum dot superlattice layer 10. Light having such a wavelength as to be absorbed by the quantum dot superlattice layer 10 can be transmitted through the tunnel layer 15.

The BSF layer 16 is formed of a III-V semiconductor to which impurities are added, for example, and is formed on the tunnel layer 15. In the present embodiment, the BSF layer 16 has a two-layer structure in which a first BSF layer 16A made from p-AlGaAs and doped with Zn and a second BSF layer 16B made from p-AlInGaP and doped with Te are sequentially stacked. In the present embodiment, the case has been described where the BSF layer 16 having the two-layer structure composed of the first BSF layer 16A and the second BSF layer 16B is adopted. However, the present invention is not limited to this case, and a single BSF layer or a BSF layer composed of three or more layers may be adopted.

The first BSF layer 16A and the second BSF layer 16B are each formed from a III-V semiconductor material having a band gap that is larger than the band gap Bg1 of the III-V semiconductors forming the buried layers 13 of the quantum dot superlattice layer 10. Light having such a wavelength as to be absorbed by the quantum dot superlattice layer 10 can be transmitted through the BSF layer 16.

In the present embodiment, the photovoltaic conversion stack part 17 is formed on a surface of the BSF layer 16. Through an internal electric field generated at the boundary between the BSF layer 16 and the photovoltaic conversion stack part 17, the BSF layer 16 pushes back, into the photovoltaic conversion stack part 17, electrons which are minority carriers generated near the boundary between the BSF layer 16 and the photovoltaic conversion stack part 17, whereby diffusion of electrons into the BSF layer 16 can be inhibited. In order to inhibit diffusion of minority carriers into the BSF layer 16, the BSF layer 16 may be formed of the same III-V semiconductor as those of the photovoltaic conversion stack part 17 so as to have a dopant concentration higher than that of the photovoltaic conversion stack part 17, or may be formed from a III-V semiconductor material having a larger band gap than those of the photovoltaic conversion stack part 17.

The photovoltaic conversion stack part 17 has a configuration in which an n-type photovoltaic conversion layer 24 formed of a Si-doped n-type III-V semiconductor such as n-InGaP is stacked on a p-type photovoltaic conversion layer 23 formed of, e.g., a Zn-doped p-type III-V semiconductor such as p-InGaP. In this case, the p-type photovoltaic conversion layer 23 and the n-type photovoltaic conversion layer 24 have the different impurities added thereto, but are formed of the same III-V semiconductors.

In the photovoltaic conversion stack part 17, a band gap Bg4 of the III-V semiconductors forming the p-type photovoltaic conversion layer 23 and the n-type photovoltaic conversion layer 24 is selected to be larger than the band gap Bg1 of the III-V semiconductors forming the buried layers 13 of the quantum dot superlattice layer 10. As a result, when light is incident, the photovoltaic conversion stack part 17 can absorb light having a wavelength corresponding to the band gap Bg4 of the III-V semiconductors forming the p-type photovoltaic conversion layer 23 and the n-type photovoltaic conversion layer 24 before the light enters the intermediate-band solar battery cell 2. Further, the photovoltaic conversion stack part 17 can transmit therethrough light having such a long wavelength as to be absorbed by the intermediate-band solar battery cell 2, thereby can cause the light having the long wavelength to reach the intermediate-band solar battery cell 2.

Here, as a result of absorbing light having a wavelength corresponding to the band gap Bg4 of the III-V semiconductors forming the p-type photovoltaic conversion layer 23 and the n-type photovoltaic conversion layer 24, the photovoltaic conversion stack part 17 causes electrons in the valence bands of the III-V semiconductors, to be excited to the conduction bands, so that holes can be generated in the valence bands and electrons can be generated in the conduction bands. In the photovoltaic conversion stack part 17, holes generated in the valence bands are diffused toward the p-type photovoltaic conversion layer 23 and electrons generated in the conduction bands are diffused toward the n-type photovoltaic conversion layer 24, by an internal electric field generated at the interface between the p-type photovoltaic conversion layer 23 and the n-type photovoltaic conversion layer 24, so that voltage and current can be generated.

The window layer 18 is formed of a Te-doped III-V semiconductor, such as n-InAlP, to which impurities are added, and is formed on the photovoltaic conversion stack part 17. Through an internal electric field generated at the boundary between the n-type photovoltaic conversion layer 24 and the window layer 18, the window layer 18 pushes back, into the n-type photovoltaic conversion layer 24, holes which are minority carriers generated in a portion, of the n-type photovoltaic conversion layer 24, near the boundary between the n-type photovoltaic conversion layer 24 and the window layer 18, so that diffusion of the holes into the window layer 18 can be inhibited.

In order to inhibit diffusion of minority carriers into the window layer 18, the window layer 18 may be formed of the same III-V semiconductor as that of the n-type photovoltaic conversion layer 24 so as to have a dopant concentration higher than that of the n-type photovoltaic conversion layer 24, or may be formed of a III-V semiconductor having a larger band gap than that of the n-type photovoltaic conversion layer 24. Here, the window layer 18 is formed of a III-V semiconductor having a band gap that is larger than the band gap Bg4 of the III-V semiconductors forming the photovoltaic conversion stack part 17, and the window layer 18 can transmit therethrough light having such a wavelength as to be absorbed by the photovoltaic conversion stack part 17.

The contact layer 19 is formed of a III-V semiconductor to which impurities are added, and can be formed on the window layer 18. The contact layer 19 can reduce a contact resistance at a joint surface relative to the surface electrodes 5 which are formed on a surface of the contact layer 19. In the present embodiment, the contact layer 19 has a configuration in which a second contact layer 19B made from n-InGaAs and doped with Te is stacked on a first contact layer 19A made from n-InGaAs and doped with Si, for example.

In this case, the first contact layer 19A and the second contact layer 19B are each formed of a III-V semiconductor having a band gap that is larger than the band gap Bg4 of the III-V semiconductors forming the photovoltaic conversion stack part 17. Thus, the first contact layer 19A and the second contact layer 19B can transmit therethrough light having such a wavelength as to be absorbed by the photovoltaic conversion stack part 17, and cause the light to reach the photovoltaic conversion stack part 17.

In the present embodiment, the case has been described where the contact layer 19 having the two-layer structure composed of the first contact layer 19A and the second contact layer 19B is adopted. However, the present invention is not limited to this case, and a single contact layer or a contact layer composed of three or more layers may be adopted. The surface electrodes 5 formed on the contact layer 19 each have a single layer structure or a multi-layer structure formed from a metal member such as Au, Ag, Ge, or Ni, and can be connected to an external circuit (not illustrated) to which the back electrode 4 is connected. The surface electrodes 5 are formed at a plurality of positions on the contact layer 19. The surface electrodes 5 are arranged at a prescribed interval. Light incident through the surface electrodes 5 toward the back electrode 4 can enter the inside through the contact layer 19 exposed between the surface electrodes 5.

FIG. 3 is a schematic diagram showing a relationship, in the solar battery 1 of the embodiment according to the present invention, among the band gap Bg1 in each of the buried layers 13 of the quantum dot superlattice layer 10 in the intermediate-band solar battery cell 2, the band gap Bg2 and the band gap Bg3 obtained by the intermediate band 27 formed in the quantum dot superlattice layer 10, and the band gap Bg4 in the photovoltaic conversion stack part 17 in the current adjusting solar battery cell 3 which is connected, at the light incidence side, in series to the intermediate-band solar battery cell 2.

In the intermediate-band solar battery cell 2, since electrons are excited from the valence band VB to the intermediate band 27 in each of the buried layers 13 of the quantum dot superlattice layer 10 and the excited electrons are excited from the intermediate band 27 to the conduction band CB of the buried layer 13, the band gap Bg2 between the valence band VB and the intermediate band 27 is considered to be connected in series to the band gap Bg3 between the intermediate band 27 and conduction band CB, as illustrated in FIG. 3. In the intermediate-band solar battery cell 2, electrons are excited not only via the intermediate band 27, but also from the valence band VB directly to the conduction band CB in each of the buried layers 13 of the quantum dot superlattice layer 10. Thus, in the buried layer 13, the band gap Bg1 between the valence band VB and the conduction band CB is considered to be connected in parallel with the serial connection between the band gap Bg2 between the valence band VB and the intermediate band 27 and the band gap Bg3 between the intermediate band 27 and the conduction band CB.

In addition, the solar battery 1 according to the present invention has the configuration in which the current adjusting solar battery cell 3 is formed on the intermediate-band solar battery cell 2, and the intermediate-band solar battery cell 2 is connected in series to the current adjusting solar battery cell 3. As a result, in the solar battery 1 according to the present invention, the band gap Bg4 in the photovoltaic conversion stack part 17 of the current adjusting solar battery cell 3 is considered to be connected in series to the band gap Bg1 in the buried layers 13 of the quantum dot superlattice layer 10 of the intermediate-band solar battery cell 2. Further, the band gap Bg4 in the photovoltaic conversion stack part 17 of the current adjusting solar battery cell 3 is considered to be connected directly to the band gap Bg2 between the valence band VB and the intermediate band 27 and the band gap Bg3 between the intermediate band 27 and the conduction band CB.

Accordingly, in the solar battery 1 according to the present invention, voltage obtained by including the voltage obtained on the basis of the band gaps Bg1, Bg2, Bg3 in the intermediate-band solar battery cell 2, and the voltage obtained on the basis of the band gap Bg4 in the current adjusting solar battery cell 3 can be obtained as the overall output voltage. Consequently, the overall output voltage can be increased by an amount of the voltage obtained on the basis of the band gap Bg4 in the current adjusting solar battery cell 3.

Here, in the solar battery 1 according to the present invention, the current adjusting solar battery cell 3 absorbs light having a wavelength corresponding to the band gap Bg4, and an amount of light to be absorbed by the intermediate-band solar battery cell 2 is accordingly reduced, whereby an amount of current in the intermediate-band solar battery cell 2 can be reduced.

In the intermediate-band solar battery cell 2 including the layers formed of the III-V semiconductors as illustrated in FIG. 1, when the band gap Bg1 in the buried layers 13 is 1.4 eV, the band gap Bg2 between the valence band VB and the intermediate band 27 and the band gap Bg3 between the intermediate band 27 and the conduction band CB in the buried layers 13 of the quantum dot superlattice layer 10, can be set to 1.0 eV and 0.4 eV, respectively, by adjusting the arrangement of the quantum dots 12 in the quantum dot superlattice layer 10, for example.

In this case, in the current adjusting solar battery cell 3 including the layers formed of the III-V semiconductors as illustrated in FIG. 1, the band gap Bg4 in the photovoltaic conversion stack part 17 can be set to 1.7 eV greater than 1.4 eV which is the band gap Bg1 in the buried layers 13 in the intermediate-band solar battery cell 2, for example.

As a result of this, in the solar battery 1, when light is applied onto the surface electrodes 5 toward the back electrode 4, a part of the light having a wavelength of at most 729 nm corresponding to 1.7 eV, which is set as the band gap Bg4 in the photovoltaic conversion stack part 17 of the current adjusting solar battery cell 3, is absorbed by the photovoltaic conversion stack part 17, so that voltage and current can be outputted. Further, a part of the light having a wavelength longer than 729 nm passes through the current adjusting solar battery cell 3 and enters the intermediate-band solar battery cell 2.

In the intermediate-band solar battery cell 2, light having passed through the current adjusting solar battery cell 3 and having a wavelength of at most 886 nm corresponding to 1.4 eV, which is the band gap Bg4 in the buried layers 13 of the quantum dot superlattice layer 10, is absorbed by the quantum dot superlattice layer 10, so that voltage and current can be outputted. Further, the intermediate-band solar battery cell 2 absorbs light having a wavelength of at most 1240 nm corresponding to 1.0 eV, which is the band gap Bg2 between the valence band VB and the intermediate band 27 in each of the buried layers 13, and also absorbs light having a wavelength of at most 3100 nm corresponding to 0.4 eV, which is the band gap Bg3 between the intermediate band 27 and the conduction band CB, so that voltage and current can be outputted by the light absorption.

As described above, in the solar battery 1 according to the present invention, the current adjusting solar battery cell 3 absorbs light having a wavelength corresponding to the band gap Bg4, and an amount of light to be absorbed by the intermediate-band solar battery cell 2 is accordingly reduced, whereby an amount of current in the intermediate-band solar battery cell 2 can be reduced. Also, not only the voltage based on the band gaps Bg1, Bg2, Bg3 in the intermediate-band solar battery cell 2, but also the voltage obtained based on the band gap Bg4 in the current adjusting solar battery cell 3 are obtained, and the overall output voltage of the solar battery 1 can be accordingly increased.

2. Method for Manufacturing Solar Battery According to Present Invention

Next, a simple description of a method for manufacturing the above solar battery 1 is given. In this case, first, the substrate 6 is prepared so as to have the back surface on which the back electrode 4 is formed by a vacuum deposition method or the like. The substrate 6 is placed in a chamber of a molecular beam epitaxy (MBE) film-forming device. The first buffer layer 7A, the second buffer layer 7B, the p-type semiconductor layer 9, the first quantum dot buffer layer 10A, the quantum dot layers 10B, the second quantum dot buffer layer 10C, and the n-type semiconductor layer 11 are sequentially formed on a surface of the substrate 6 by an MBE method. Thus, the intermediate-band solar battery cell 2 is fabricated. Here, the first buffer layer 7A, the second buffer layer 7B, the p-type semiconductor layer 9, the first quantum dot buffer layer 10A, the second quantum dot buffer layer 10C, and the n-type semiconductor layer 11 are continuously formed by being respectively epitaxially grown, and thereby are formed into a single crystal by lattice-matching at joint surfaces therebetween.

For example, each of the aforementioned quantum dot layers 10B is obtained by forming the plurality of quantum dots 12 on the first quantum dot buffer layer 10A through self-assembly using Stranski-Krastanov (S-K) growth, and forming the buried layer 13 on the first quantum dot buffer layer 10A so as to cover the quantum dots 12. Then, the plurality of quantum dots 12 are formed on the buried layer 13 through self-assembly, and the quantum dots 12 are covered with the buried layer 13. This process is repeated to sequentially stack one of the quantum dot layers 10B on another.

Next, the intermediate-band solar battery cell 2 is extracted from the chamber of the MBE film-forming device, and is transported into a chamber of a metal organic chemical vapor deposition (MOCVD) film-forming device. During the transport, the intermediate-band solar battery cell 2 is exposed to the atmosphere. Therefore, a surface of the intermediate-band solar battery cell 2 placed in the chamber is etched so that the surface contaminated due to the exposure to the atmosphere is removed. Next, the n-type tunnel layer 21, the p-type tunnel layer 22, the first BSF layer 16A, the second BSF layer 16B, the p-type photovoltaic conversion layer 23, the n-type photovoltaic conversion layer 24, the window layer 18, the first contact layer 19A, and the second contact layer 19B are sequentially formed, by an MOCVD method, on the intermediate-band solar battery cell 2 the surface of which has been etched. Thus, the current adjusting solar battery cell 3 is fabricated.

Here, the n-type tunnel layer 21, the p-type tunnel layer 22, the first BSF layer 16A, the second BSF layer 16B, the p-type photovoltaic conversion layer 23, the n-type photovoltaic conversion layer 24, the window layer 18, the first contact layer 19A, and the second contact layer 19B are continuously formed by being epitaxially grown, and thereby are formed into a single crystal by lattice-matching at joint surfaces therebetween. At last, a metal film is formed on the current adjusting solar battery cell 3 by a vacuum deposition method or the like, and a plurality of the surface electrodes 5 each having a prescribed shape are formed, by photolithography, on the current adjusting solar battery cell 3. Thus, the solar battery 1 can be fabricated.

3. Operation and Effects

The solar battery 1 according to the present invention having the aforementioned configuration is provided with: the intermediate-band solar battery cell 2 in which the quantum dot layers 10B each having the plurality of quantum dots 12 arranged in the buried layer 13 are stacked, and the wavefunctions of the quantum dots 12 are superposed one another to form the intermediate band 27; and the current adjusting solar battery cell 3 which includes the photovoltaic conversion stack part 17 having the band gap Bg4 larger than the band gap Bg1 in the buried layers 13 of the intermediate-band solar battery cell 2. The current adjusting solar battery cell 3 is formed at the light incident side of the intermediate-band solar battery cell 2.

Accordingly, in the solar battery 1, while a part of incident light having a wavelength equal to or shorter than a wavelength corresponding to the band gap Bg4 is absorbed by the current adjusting solar battery cell 3 so that voltage and current are generated at the current adjusting solar battery cell 3, a part of the light having other wavelengths can pass through the current adjusting solar battery cell 3 and enter the intermediate-band solar battery cell 2.

Accordingly, in the solar battery 1, light having a wavelength not longer than a wavelength corresponding to the band gap Bg4 is absorbed by the current adjusting solar battery cell 3, and an amount of light to be absorbed by the intermediate-band solar battery cell 2 is accordingly reduced, whereby an amount of current which is generated in the intermediate-band solar battery cell 2 can be reduced. Consequently, an amount of heat which is generated in the intermediate-band solar battery cell 2 can be accordingly reduced. Consequently, thermal damage to the solar battery 1 can be prevented.

Further, in the solar battery 1, while an amount of current which is generated in the intermediate-band solar battery cell 2 is reduced by means of the current adjusting solar battery cell 3, voltage is generated, by absorption of light having a wavelength corresponding to the band gap Bg4, also in the current adjusting solar battery cell 3 connected in series to the intermediate-band solar battery cell 2. Thus, the overall output voltage obtained by the solar battery 1 can be increased by means of the intermediate-band solar battery cell 2 and the current adjusting solar battery cell 3 connected in series to each other. Consequently, the conversion efficiency can be greatly enhanced compared with conventional solar batteries.

4. Verification Test

### (1) Simulation Test

Next, a simulation test using a detailed balance model was conducted by preparing the solar battery 1 according to the present invention as an experimental example, and preparing a conventional intermediate-band solar battery as a comparative example, so that a current-voltage curve and a conversion efficiency of each of the examples were calculated to evaluate the electric characteristics. A value of the conversion efficiency was calculated by using, as the spectrum of sunlight, the spectrum of 6000K blackbody radiation (air mass: 0).

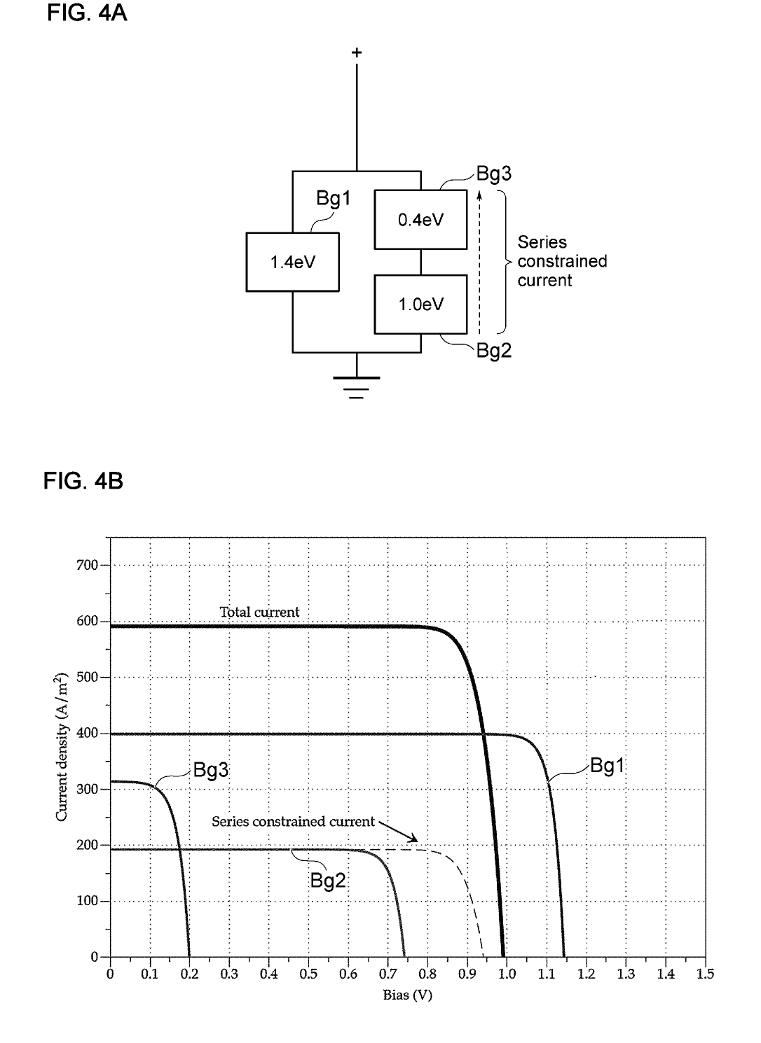

First, a simulation test of the comparative example, which is a conventional intermediate-band solar battery, was conducted. In the comparative example as illustrated in FIG. 4A, the largest band gap Bg1 between the valence band and the conduction band was set to 1.4 eV, the band gap Bg2 between the valence band and the intermediate band was set to 1.0 eV, and the band gap Bg3 between the intermediate band and the conduction band was set to 0.4 eV.

Also in the comparative example, the simulation test was conducted in which the band gap Bg2 between the valence band and the intermediate band was considered to be connected in series to the band gap Bg3 between the intermediate band and the conduction band, and the band gap Bg1 between the valence band and the conduction band was considered to be connected in parallel with the band gap Bg2 and the band gap Bg3.

FIG. 4B shows a current-voltage curve obtained when the simulation test of the comparative example illustrated in FIG. 4A was conducted. In FIG. 4B, the abscissa shows the voltage and the ordinate shows the current density. “Total current” in FIG. 4B indicates a current-voltage curve in the entire conventional intermediate-band solar battery as the comparative example. In FIG. 4B, a curve denoted by “Bg1” is a current-voltage curve of current and voltage generated by absorption of light corresponding to the band gap Bg1 (1.4 eV) illustrated in FIG. 4A, a curve denoted by “Bg2” is a current-voltage curve of current and voltage generated by absorption of light corresponding to the band gap Bg2 (1.0 eV) in FIG. 4A, and “Bg3” is a current-voltage curve of current and voltage generated by absorption of light corresponding to the band gap Bg3 (0.4 eV) in FIG. 4A. “Series constrained current” (a broken line) in FIG. 4B indicates an overall current-voltage curve of the band gap Bg2 and the band gap Bg3 connected in serial to each other.

In the comparative example as shown in FIG. 4B, a short-circuit current density, which is a current value when the voltage is zero, was approximately 600 A/m², whereas an open-circuit voltage, which is a voltage value when the current is zero, was approximately 1.0 V. In the comparative example, the conversion efficiency calculated from the current-voltage curves was approximately 37%.

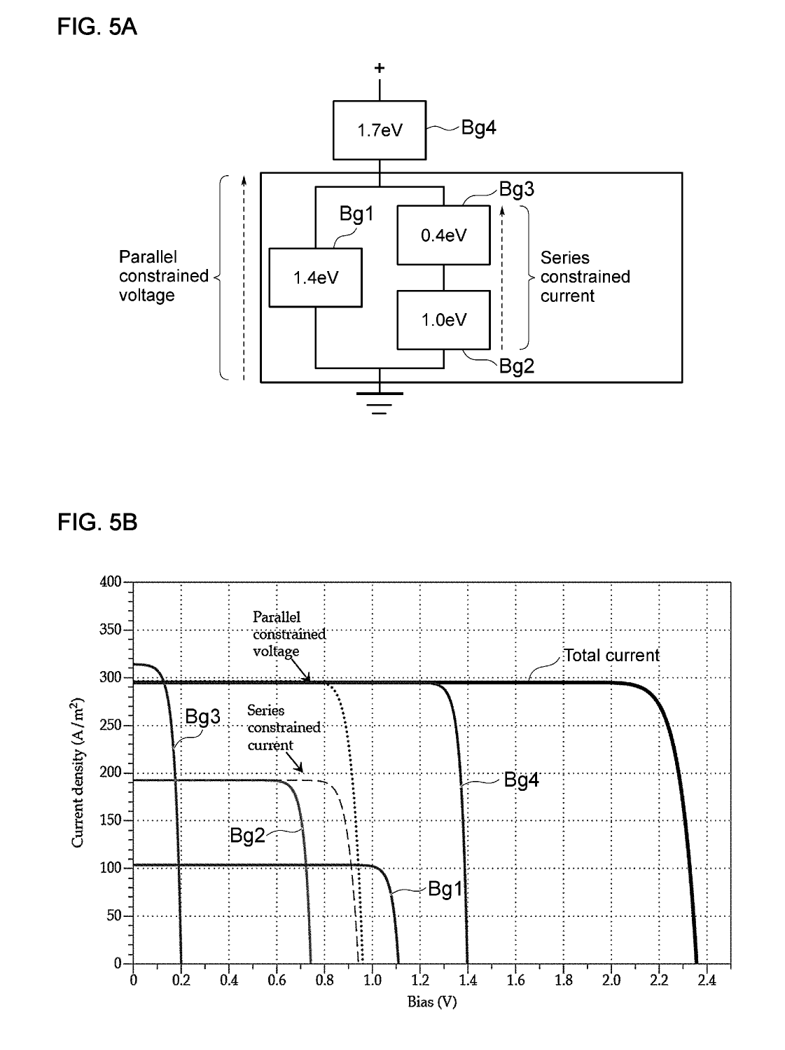

Next, a simulation test of the solar battery 1 according to the present invention was conducted. In this case, in the experimental example as shown in FIG. 5A, the band gap Bg1 between the valence band VB and the conduction band CB, the band gap Bg2 between the valence band VB and the intermediate band 27, and the band gap Bg3 between the intermediate band 27 and the conduction band CB in the intermediate-band solar battery cell 2 portion, were set to 1.4 eV, 1.0 eV, and 0.4 eV, respectively, which were equal to those in the comparative example in FIG. 4A.

In addition, in the experimental example, the current adjusting solar battery cell 3 having the band gap Bg4, which was longer than any of the band gaps Bg1, Bg2, Bg3 in the intermediate-band solar battery cell 2, was configured such that the band gap Bg4 in the current adjusting solar battery cell 3 was set to 1.7 eV, and that the band gap Bg4 in the current adjusting solar battery cell 3 was connected in series to the band gap Bg1 and to the band gap Bg2 and the band gap Bg3, formed by the intermediate band, in the intermediate-band solar battery cell 2. The simulation test of the experimental example having this configuration was conducted.

FIG. 5B shows a current-voltage curve which was obtained when the simulation test of the experimental example illustrated in FIG. 5A was conducted. The curve denoted by “Bg4” in FIG. 5B is a current-voltage curve of current and voltage generated by absorption of light corresponding to the band gap Bg4 in the current adjusting solar battery cell 3. “Parallel constrained voltage” (a dotted line) in FIG. 5B indicates a current-voltage curve of total current and total voltage obtained on the basis of the band gap Bg1, the band gap Bg2, and the band gap Bg3 in the intermediate-band solar battery cell 2. “Bg1”, “Bg2”, “Bg3”, and “Series constrained current” in FIG. 5B are identical to those in FIG. 4B, and thus, the explanation thereof is omitted.

As shown in FIG. 5B, in the solar battery 1 as the experimental example, the short-circuit current density was approximately 300 A/m², and the open-circuit voltage was approximately 2.35 V. In the experimental example, the conversion efficiency calculated from the current-voltage curves achieved approximately 46%. Thus, it was confirmed that the conversion efficiency was greatly enhanced compared with the comparative example.

In the experimental example, it was confirmed that the overall short-circuit current density was lower than that in the comparative example, the overall flowing current was suppressed, and an amount of heat which was generated by the current was reduced. Further, it was confirmed that the conversion efficiency was enhanced even though reduction in the short-circuit current density. That is, it was confirmed that, in the experimental example, the overall output voltage was increased by the voltage generated in the current adjusting solar battery cell 3, and thus, the overall conversion efficiency was not reduced even though reduction in the output current from the intermediate-band solar battery cell 2, whereby enhancement of the overall conversion efficiency was succeeded.

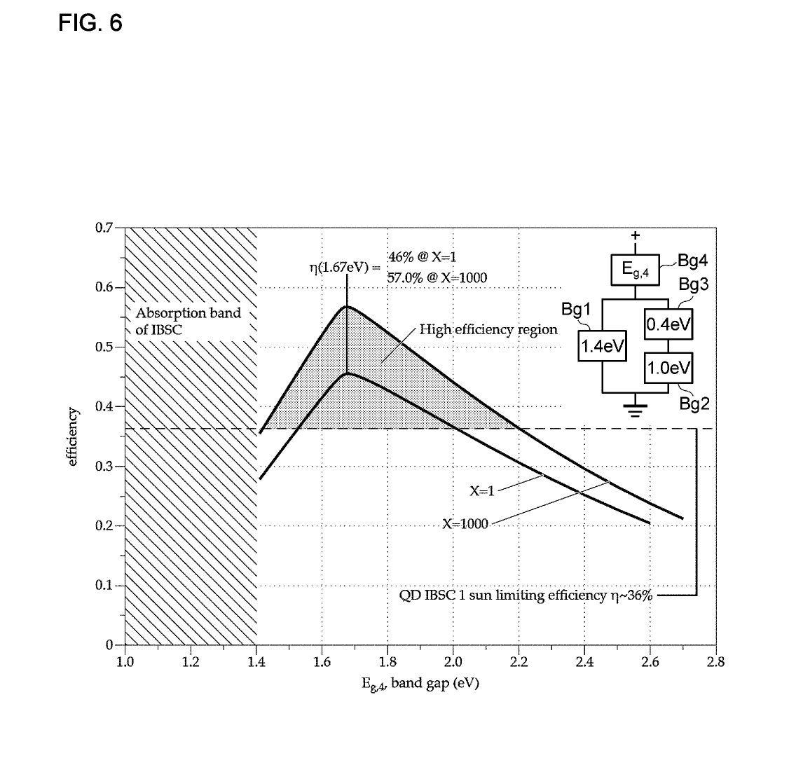

Next, the value of the band gap Bg4 in the current adjusting solar battery cell 3 was defined as Eg,4, and the overall conversion efficiency of the solar battery 1 was calculated to check the relationship between Eg,4 of the band gap Bg4 in the current adjusting solar battery cell 3 and the overall conversion efficiency of the solar battery 1. The result shown in FIG. 6 was obtained. Note that the value of the band gap Bg1 and the values of the band gap Bg2 and the band gap Bg3 formed by the intermediate band in the intermediate-band solar battery cell 2 were set to be equal to those in the example shown in FIG. 5A.

In FIG. 6, the abscissa shows the value Eg,4 of the band gap Bg4 and the ordinate shows the conversion efficiency. In FIG. 6, “X=1” indicates the result obtained when the light concentration ratio was set to 1, and “X=1000” indicates the result obtained when the light concentration ratio was set to 1000. The broken line in FIG. 6 indicates the maximum value 36% of the conversion efficiency obtained when no band gap Bg4 is provided (when the light concentration ratio is 1). As shown in FIG. 6, it was confirmed that when the value Eg,4 of the band gap Bg4 was within a range of approximately 1.55 to 1.9 eV, the conversion efficiency was extremely high to exceed 50%.

Therefore, it was found that when the value of the largest band gap Bg1 in the intermediate-band solar battery cell 2 is selected to 1.4 eV or less, the overall conversion efficiency of the solar battery 1 can be enhanced by selecting the band gap Bg4 in the current adjusting solar battery cell 3 to approximately 1.55 to 1.9 eV.

(2) Experimental Test

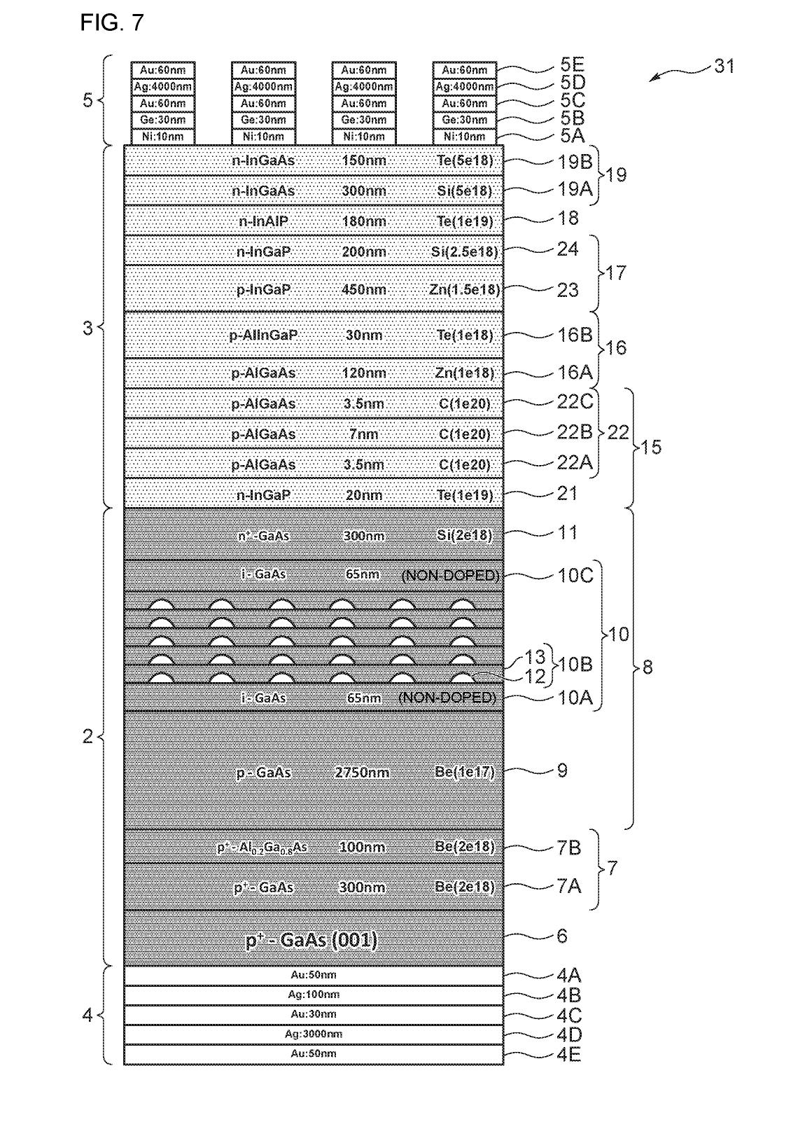

Next, a solar battery 31 according to the present invention, as illustrated in FIG. 7 in which the corresponding components to those in FIG. 1 are denoted by the same reference numerals, was actually fabricated to check the current-voltage characteristics and the conversion efficiency of the solar battery 31. In this case, the solar battery 1 was different from the solar battery 1 illustrated in FIG. 1 in that the back electrode 4 had a five-layer structure, the p-type tunnel layer 22 of the current adjusting solar battery cell 3 had a three-layer structure, and the surface electrodes 5 each had a five-layer structure. In FIG. 7, the numerical values with “nm” each indicate a layer thickness, and the numerical values in parentheses each indicate the concentration of a doped dopant. In the solar battery 31, five quantum dot layers 10B of the quantum dot superlattice layer 10 of the intermediate-band solar battery cell 2 were formed.

The back electrode 4 was formed by sequentially stacking, by vacuum deposition on a surface of the substrate 6, a first back electrode layer 4A having a thickness of 50 nm and being made from Au, a second back electrode layer 4B having a thickness of 100 nm and being made from Ag, a third back electrode layer 4C having a thickness of 30 nm and being made from Au, a fourth back electrode layer 4D having a thickness of 3000 nm and being made from Ag, and a fifth back electrode layer 4E having a thickness of 50 nm and being made from Au.

The p-type tunnel layer 22 was formed by sequentially causing, on the n-type tunnel layer 21, epitaxial growth of a first p-type tunnel layer 22A having a thickness of 3.5 nm, being made from p-AlGaAs, and being doped with C in a concentration of 1.0×10²⁰/cm³, a second p-type tunnel layer 22B having a thickness of 7.0 nm, being made from p-AlGaAs, and being doped with C in a concentration of 1×10²⁰/cm³, and a third p-type tunnel layer 22C having a thickness of 3.5 nm, being made from p-AlGaAs, and being doped with C in a concentration of 1×10²⁰/cm³, by a MOCVD method.

Each of the surface electrodes 5 was formed by sequentially stacking, by vacuum deposition on the contact layer 19, a first surface electrode layer 5A having a thickness of 10 nm and being made from Ni, a second surface electrode layer 5B having a thickness of 30 nm and being made from Ge, a third surface electrode layer 5C having a thickness of 60 nm and being made from Au, a fourth surface electrode layer 5D having a thickness of 4000 nm and being made from Ag, and a fifth surface electrode layer 5E having a thickness of 60 nm and being made from Au.

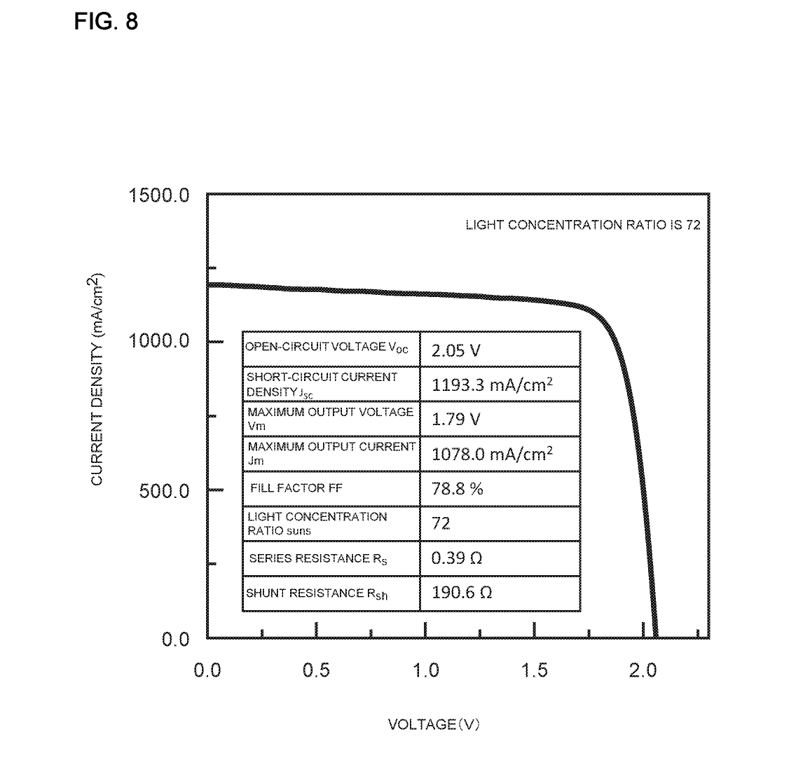

The current-voltage characteristics of the solar battery 31 having the above configuration when the light concentration ratio was 72 were measured using light satisfying a standard solar battery measurement condition (air mass: 1.5). As a result, the result shown in FIG. 8 was obtained. In FIG. 8, the abscissa shows the voltage and the ordinate shows the current density. In FIG. 8, the conversion efficiency of the solar battery 31 according to the present invention calculated from the measured current-voltage characteristics is 26.8%. Thus, it was confirmed that the conversion efficiency was greatly enhanced compared with the conversion efficiency of a conventional intermediate-band solar battery, the conversion efficiency of which is approximately 20.3% (when the light concentration ratio is 100) or is approximately 21.2% (when the light concentration ratio is 1000).

5. Modifications

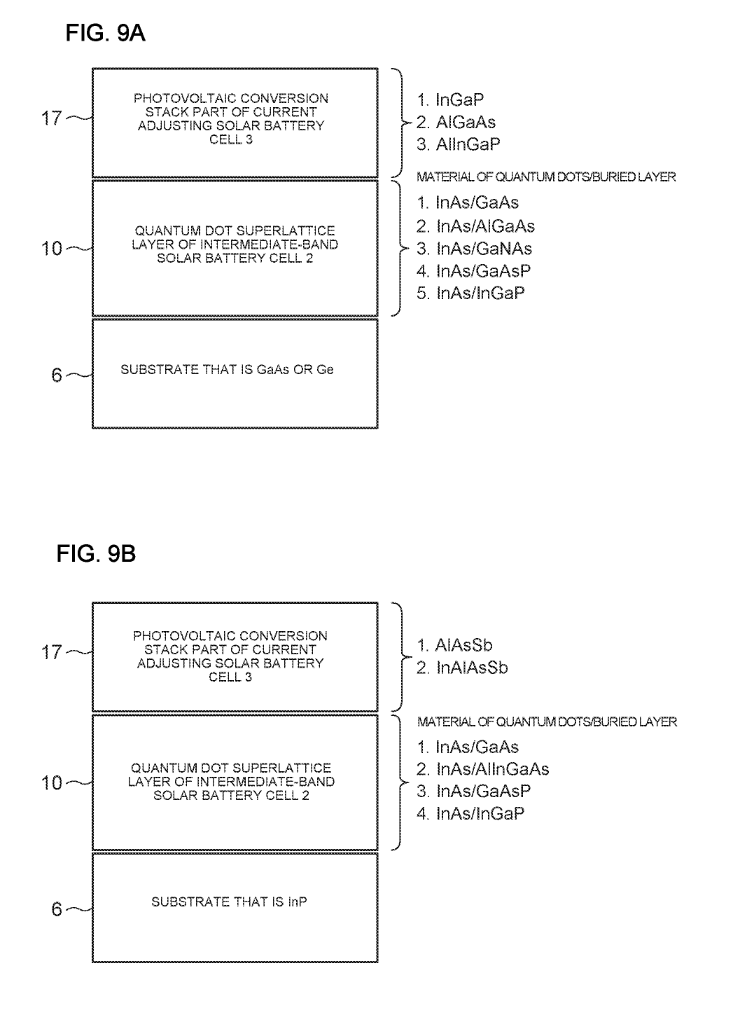

The present invention is not limited to the embodiment having been described above, and various modifications can be made within the scope of the gist of the present invention. For example, materials for forming the back electrode 4, the buffer layer 7, the p-type semiconductor layer 9, the n-type semiconductor layer 11, the tunnel layer 15, the BSF layer 16, the window layer 18, the contact layer 19, and the surface electrodes 5 may be changed, as appropriate. For example, when GaAs or Ge is selected for the substrate 6 as shown in FIG. 9A, InAs may be used as a material for forming the quantum dots 12 in the intermediate-band solar battery cell 2, and any one of GaAs, AlGaAs, GaNAs, GaAsP, and InGaP may be used as a material for forming the buried layers 13 of the quantum dot superlattice layer 10. In this case, any one of InGaP, AlGaAs, and AlInGaP may be used for the photovoltaic conversion stack part 17 of the current adjusting solar battery cell 3, and the p-type photovoltaic conversion layer 23 formed of a p-type III-V semiconductor and the n-type photovoltaic conversion layer 24 formed of an n-type III-V semiconductor may be formed. The composition of each of the p-type photovoltaic conversion layer 23 and the n-type photovoltaic conversion layer 24 is adjusted so as to have a band gap larger than those in the buried layers 13. For example, in a case where AlGaAs is used for the buried layers 13 and AlGaAs is used for the p-type photovoltaic conversion layer 23 and the n-type photovoltaic conversion layer 24, the Al composition of each of the buried layers 13 is set to approximately 30% less than 50% which is the Al composition of each of the p-type photovoltaic conversion layer 23 and the n-type photovoltaic conversion layer 24.

In still another embodiment as illustrated in FIG. 9B, for example, when InP is selected for the substrate 6, InAs may be used as a material for forming the quantum dots 12 in the intermediate-band solar battery cell 2 and any one of GaAs, AlInGaAs, GaAsP, and InGaP may be used for a material for forming the buried layers 13 of the quantum dot superlattice layer 10. In this case, AlAsSb or InAlAsSb may be used for the photovoltaic conversion stack part 17 of the current adjusting solar battery cell 3, and the p-type photovoltaic conversion layer 23 formed of a p-type III-V semiconductor and the n-type photovoltaic conversion layer 24 formed of an n-type III-V semiconductor may be formed.

In the embodiment having been described above, the case has been described where the photovoltaic conversion stack part 17 of the current adjusting solar battery cell 3 is a pn junction. However, the present invention is not limited to this case, and the photovoltaic conversion stack part 17 may be a pin junction having a three-layer structure of a p-type semiconductor/an intrinsic semiconductor/an n-type semiconductor.

In the embodiment having been described above, the case has been described where the tunnel layer 15 is formed in the current adjusting solar battery cell 3. However, forming the tunnel layer 15 may be omitted. For example, the BSF layer 16 of the current adjusting solar battery cell 3 may be epitaxially grown on the n-type semiconductor layer 11 of the intermediate-band solar battery cell 2, and a joint surface of the n-type semiconductor layer 11 and a joint surface of the BSF layer 16 may be lattice-matched. The intermediate-band solar battery cell 2 and the current adjusting solar battery cell 3 may be separately fabricated, and the n-type semiconductor layer 11 of the intermediate-band solar battery cell 2 and the BSF layer 16 of the current adjusting solar battery cell 3 may be bonded together with an adhesive having conductivity and having a band gap larger than the band gap Bg1 of the III-V semiconductors forming the buried layers 13.

In still another embodiment, the conductive types of the p-type and the n-type of each layer of the solar battery 1 illustrated in FIG. 1 may be inversed. That is, the above embodiment illustrated in FIG. 1 adopts the intermediate-band solar battery cell 2 in which the quantum dot superlattice layer 10 is formed between the p-type semiconductor layer 9 and the n-type semiconductor layer 11, and the p-type semiconductor layer 9 is formed on the p-type buffer layer 7. However, the present invention is not limited to this embodiment. An intermediate-band solar battery cell may be provided by inversing the p-type and the n-type so as to form the quantum dot superlattice layer 10 between the p-type semiconductor layer 9 and the n-type semiconductor layer 11, and form the n-type semiconductor layer 11 on an n-type buffer layer.

In a case where the conductive types of the p-type and the n-type are inversed in the intermediate-band solar battery cell 2, the conductive types of the p-type and the n-type in the current adjusting solar battery cell 3 need to be inversed correspondingly. That is, as illustrated in FIG. 1, the case has been described where the current adjusting solar battery cell 3 adopts the photovoltaic conversion stack part 17 having the configuration in which the p-type photovoltaic conversion layer 23 formed of a p-type III-V semiconductor and the n-type photovoltaic conversion layer 24 formed of an n-type III-V semiconductor are joined together, the p-type photovoltaic conversion layer 23 is formed on the p-type BSF layer 16, and the n-type window layer 18 is formed on the n-type photovoltaic conversion layer 24. However, the present invention is not limited this case. A photovoltaic conversion stack part may be adopted in which the conductive types of the p-type and the n-type are inversed such that an n-type photovoltaic conversion layer is formed on an n-type BSF layer and a p-type window layer is formed on a p-type photovoltaic conversion layer.

In the embodiment having been described above, the case has been described where the intermediate-band solar battery cell 2 and the current adjusting solar battery cell 3 are epitaxially grown on the substrate 6 so that the joint surface of the intermediate-band solar battery cell 2 and the joint surface of the current adjusting solar battery cell 3 are lattice-matched. However, the present invention is not limited to this case. For example, as yet another embodiment, instead of continuous forming of the intermediate-band solar battery cell 2 and the current adjusting solar battery cell 3 through the epitaxial growth thereof using the substrate 6, the intermediate-band solar battery cell 2 and the current adjusting solar battery cell 3 that are fabricated in advance without using the substrate 6 may be bonded together by a substrate bonding technique so as to form the current adjusting solar battery cell 3 on the light incidence side of the intermediate-band solar battery cell 2.

### REFERENCE SIGNS LIST

1 solar battery
2 intermediate-band solar battery cell
3 current adjusting solar battery cell
10 quantum dot superlattice layer
10B quantum dot layer
12 quantum dot
13 buried layer
17 photovoltaic conversion stack part

1. A solar battery comprising:
an intermediate-band solar battery cell that has a quantum dot superlattice layer including a plurality of quantum dot layers stacked on each other, each quantum dot layer including a buried layer having a plurality of quantum dots arranged therein, the quantum dot superlattice layer having therein an intermediate band formed by superposition of wavefunctions among the quantum dots; and
a current adjusting solar battery cell that has a photovoltaic conversion stack part including at least a p-type photovoltaic conversion layer and an n-type photovoltaic conversion layer and that is formed on a light incidence side of the intermediate-band solar battery cell, wherein
in the current adjusting solar battery cell, the photovoltaic conversion stack part has a band gap larger than a band gap in the buried layer of the intermediate-band solar battery cell.

2. The solar battery according to claim 1, wherein
the quantum dots are formed from InAs,
the buried layer is formed from any one of GaAs, AlGaAs, GaNAs, GaAsP, and InGaP, and
the p-type photovoltaic conversion layer and the n-type photovoltaic conversion layer are each formed from any one of InGaP, AlGaAs, and AlInGaP.

3. The solar battery according to claim 1, wherein
the quantum dots are formed from InAs,
the buried layer is formed from any one of GaAs, AlInGaAs, GaAsP, and InGaP, and
the p-type photovoltaic conversion layer and the n-type photovoltaic conversion layer are each formed from any one of AlAsSb and InAlAsSb.

4. The solar battery according to claim 1, wherein
the current adjusting solar battery cell includes a tunnel layer formed of a pn junction, and is joined to the intermediate-band solar battery cell through the tunnel layer.

5. The solar battery according to claim 1, wherein
the current adjusting solar battery cell is formed by being epitaxially grown on the intermediate-band solar battery cell, and is lattice-matched with a joint surface of the intermediate-band solar battery cell.

6. The solar battery according to claim 1, wherein
a band gap in the photovoltaic conversion stack part is selected within a range of 1.55 to 1.9 eV.
